(19) United States
(12) Patent Application Publication
(10) Pub. No.: US 2020/0411588 A1
(43) Pub. Date: Dec. 31, 2020

(54) Full-Color Led Diplay Panel And Method For Manufacturing Same

(71) Applicant: V Technology Co., Ltd., Yokohama-shi (JP)

(72) Inventors: Koichi Kajiyama, Yokohama-shi (JP); Takafumi Hirano, Yokohama-shi (JP)

(73) Assignee: V Technology Co., Ltd., Yokohama-shi (JP)

(21) Appl. No.: 16/930,873

(22) Filed: Jul. 16, 2020

Related U.S. Application Data
(63) Continuation of application No. PCT/JP2019/001987, filed on Jan. 23, 2019.

(30) Foreign Application Priority Data
Feb. 5, 2018 (JP) 2018-018009

(51) Int. Cl. H01L 27/15; H01L 33/50; H01L 33/60; H01L 33/00; H01L 33/48

(52) U.S. Cl. CPC H01L 27/156; H01L 33/504; H01L 33/60; H01L 2933/0066; H01L 33/486; H01L 2933/0041; H01L 33/005

(57) ABSTRACT

The present invention is a full-color LED display panel including: an LED array substrate 1 in which multiple LEDs 4 are arranged in a matrix form on a wiring board 5, each LED 4 emitting light in an ultraviolet or blue wavelength band; multiple fluorescent layers 2 configured to perform wavelength conversion by being excited by excitation light emitted from a corresponding LED 4 and by emitting fluorescence of a corresponding color, each fluorescent layer 2 being formed in an island pattern, on at least one corresponding LED 4 for red, green, or blue color, and being made of a fluorescent resist containing a fluorescent colorant uniformly dispersed in a photosensitive resin; and a light shielding member 3 that reflects or absorbs excitation light and fluorescence, and is deposited on a peripheral face 2b of each fluorescent layer 2, which is other than a light emitting surface 2a.

This application is a continuation application of PCT/JP2019/001987, filed on Jan. 23, 2019.

### FIELD OF THE INVENTION

The present invention relates to full-color LED display panels including fluorescent layers, and more specifically, relates to full-color LED display panels capable of reliably preventing mixing of colors occurring between adjacent fluorescent layers, and methods for manufacturing the full-color LED display panels.

### DESCRIPTION OF RELATED ART

A conventional full-color LED display panel is provided with: an array of micro LED devices, each emitting blue (e.g., 450 nm to 495 nm) light or deep blue (e.g., 420 nm to 450 nm) light; and an array of wavelength conversion layers (fluorescent layers) disposed over the array of the micro LED devices, each wavelength conversion layer absorbing the blue or deep blue light emitted from a corresponding micro LED device to convert the emission wavelength into the wavelength of red, green, or blue light (see, for example, JP 2016-523450 A).

However, in such a conventional full-color LED display panel, a black matrix is used as a partition wall for separating wavelength conversion layers (fluorescent layers) for red, green and blue colors. Thus, when a photosensitive resin containing a black pigment is used as the black matrix in a case in which the wavelength conversion layers are thick, there is a concern that a deep portion of the resin will be prevented from being exposed to the light due to the light shielding performance of the black matrix, and that an unexposed portion will remain. Therefore, when loading a fluorescent resist solution containing a fluorescent colorant (pigment or dye) of the corresponding color into openings (pixels) for each color surrounded by the partition walls, a part of the partition wall may collapse, and the fluorescent resist solution may leak into an adjacent opening for another color. Thus, there is a concern that this may result in colors being mixed. In particular, these problems become particularly notable when the partition walls have great height-to-width aspect ratios.

### SUMMARY OF THE INVENTION

Thus, in view of the above problems, an object of the present invention is to provide a full-color LED display panel capable of reliably preventing mixing of colors occurring between adjacent fluorescent layers, and to provide a method for manufacturing the full-color LED display panel.

To achieve the object, a full-color LED display panel according to the present invention includes:

an LED array substrate in which multiple LEDs are arranged in a matrix form on a wiring board, each LED emitting light in an ultraviolet or blue wavelength band;

multiple fluorescent layers configured to perform wavelength conversion by being excited by excitation light emitted from a corresponding LED and by emitting fluorescence of a corresponding color, each fluorescent layer being formed in an island pattern, on at least one corresponding LED for red, green, or blue color, and being made of a fluorescent resist containing a fluorescent colorant uniformly dispersed in a photosensitive resin; and

a light shielding member that reflects or absorbs excitation light and fluorescence, and is deposited on a peripheral face of each fluorescent layer, which is other than a light emitting surface.

A method for manufacturing a full-color LED display panel according to the present invention includes:

a first step of arranging multiple LEDs in a matrix form on a wiring board to form an LED array substrate, each LED emitting light in an ultraviolet or blue wavelength band;

a second step of exposing a fluorescent resist containing a fluorescent colorant uniformly dispersed in a photosensitive resin, and then, developing the fluorescent resist, to form multiple fluorescent layers configured to perform wavelength conversion by being excited by excitation light emitted from an LED and by emitting fluorescence of a corresponding color, each fluorescent layer being formed in an island pattern, on at least one corresponding LED for red, green, or blue color; and

a third step of depositing, on a peripheral face of each fluorescent layer, which is other than a light emitting surface, a light shielding member that reflects or absorbs excitation light and fluorescence.

Since, in the present invention, there is provided the light shielding member deposited on the peripheral face, which is other than the light emitting surface, of the fluorescent layer formed in the island pattern and made of the fluorescent resist, unlike the related art, there is no risk that a part of a partition wall between adjacent fluorescent layers collapses and a fluorescent resist solution leaks into an adjacent pixel for another color, to mix colors. Therefore, it is possible to reliably prevent mixing of colors occurring between adjacent fluorescent layers.

### BRIEF DESCRIPTION OF THE DRAWINGS

FIG. 1 is a plan view showing a full-color LED display panel according to a first embodiment of the present invention.

FIG. 2 is an enlarged cross-sectional view of the main part of FIG. 1.

FIG. 3 is a cross-sectional view for explaining electrical connection between electrodes of an LED of the full-color LED display panel and corresponding electrode pads of a wiring board, according to the present invention.

FIG. 4 is a graph showing an example of emission spectra of a red fluorescent layer of the full-color LED display panel according to the present invention.

FIG. 5 is a table showing an example of color purities of the red fluorescent layer of the full-color LED display panel according to the present invention.

FIGS. 6A to 6E are explanatory views showing a process for manufacturing an LED array substrate in a manufacturing method according to the first embodiment.

FIGS. 7A to 7D are explanatory views showing a process for forming fluorescent layers in the manufacturing method according to the first embodiment.

FIGS. 8A and 8B are explanatory views showing a process for forming a light shielding member in the manufacturing method according to the first embodiment.

FIG. 9 is an enlarged cross-sectional view of the main part of a full-color LED display panel according to a second embodiment of the present invention.

FIGS. 10A to 10F are explanatory views showing a process for manufacturing a fluorescent layer array substrate in a manufacturing method according to the second embodiment.

FIGS. 11A and 11B are explanatory views showing an assembling process in the manufacturing method according to the second embodiment.

### DESCRIPTION OF PREFERRED EMBODIMENTS

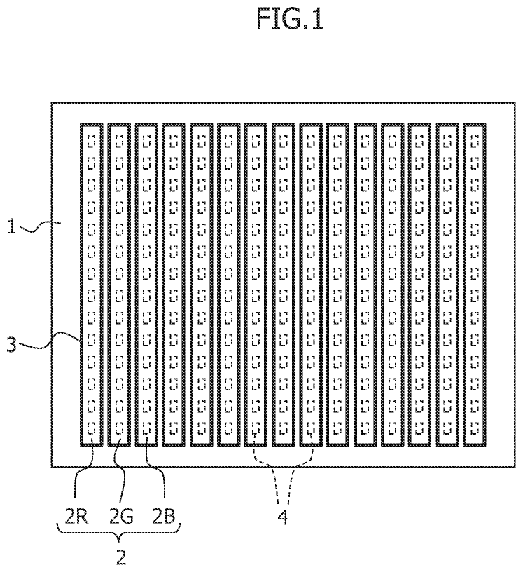

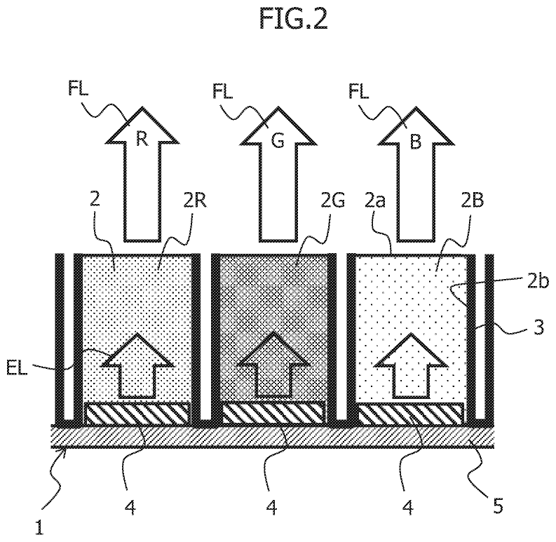

Hereinbelow, embodiments of the present invention will be described in detail with reference to the accompanying drawings. FIG. 1 is a plan view showing a full-color LED display panel according to a first embodiment of the present invention. FIG. 2 is an enlarged cross-sectional view of the main part of FIG. 1. The full-color LED display panel displays images in full color, and includes an LED array substrate 1, fluorescent layers 2, and a light shielding member 3.

The LED array substrate 1 is provided with multiple LEDs 4 arranged in a matrix form, as shown in FIG. 1. The LED array substrate 1 includes the multiple LEDs 4 arranged on a wiring board 5, which includes a flexible board or a TFT drive board including wiring for supplying a drive signal to each LED 4 from a drive circuit provided externally, and for driving the LEDs 4 individually to be ON and OFF to turn the LEDs 4 on and off

The multiple LEDs 4 are provided on the wiring board 5, as shown in FIG. 2. Each LED 4 emits light in an ultraviolet or blue wavelength band. The LEDs 4 are manufactured using gallium nitride (GaN) as a main material. Each LED 4 may be an LED that emits a near-ultraviolet light having a wavelength of, for example, 200 nm to 380 nm, or may be an LED that emits a blue light having a wavelength of, for example, 380 nm to 500 nm. As used herein, “upside” refers to a side of the display surface of the display panel, regardless of the installation state of the full-color LED display panel.

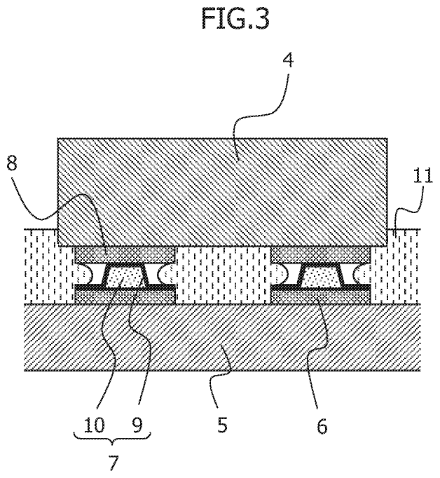

Specifically, as shown in FIG. 3, an LED 4 is configured such that each electrode 8 of the LED 4 and a corresponding electrode pad 6 of the wiring board 5 are electrically connected through a conductive elastic protrusion 7 formed on the electrode pad 6 by patterning.

More specifically, elastic protrusions 7 may be resin protrusions 10 each having a surface on which a conductive film 9 of superior conductivity, such as gold or aluminum, is deposited, or may be protrusions 10 each made of a conductive photoresist obtained by adding conductive fine particles, such as silver, to a photoresist, or be made of a conductive photoresist containing a conductive polymer. Although FIG. 3 illustrates, as an example, a case in which the protrusions 10, each having the surface on which the conductive film 9 is deposited, are formed as elastic protrusions 7, the elastic protrusions 7 may be made of a conductive photoresist.

Furthermore, as shown in FIG. 3, the LED 4 is bonded to the wiring board 5 by means of an adhesive layer 11 provided around the electrode pads 6 of the wiring board 5. In this case, the adhesive layer 11 is preferably a photosensitive adhesive that is capable of being subjected to patterning by exposure and development. Alternatively, the adhesive layer 11 may be an underfill agent or may be an ultraviolet-curable adhesive.

On each LED 4 on the LED array substrate 1, a fluorescent layer 2 is provided, as shown in FIG. 2. The fluorescent layers 2 perform wavelength conversion by being excited by excitation light EL emitted from the LEDs 4 and by emitting fluorescence FL of the corresponding colors. The fluorescent layers 2 include a red fluorescent layer 2R, a green fluorescent layer 2G, and a blue fluorescent layer 2B, which are arranged side by side on corresponding LEDs 4 in a manner corresponding to the three primary colors of light, that is, red, green and blue. Each fluorescent layer 2 is formed in an island pattern by photolithography, by exposing and developing a fluorescent resist containing a uniformly dispersed fluorescent colorant (pigment or dye) of a corresponding color. Although FIG. 1 shows a case in which the fluorescent layers 2 for red, green, and blue colors are arranged in the form of stripes, a fluorescent layer 2 may be provided on every LED 4 individually.

Specifically, each fluorescent layer 2 contains, in a resist film, a fluorescent colorant having a particle diameter of several micrometers, and an adjustment colorant having a particle diameter of several tens of nanometers and selectively transmitting light in a predetermined wavelength band. The fluorescent colorant and the adjustment colorant are uniformly mixed and dispersed in the resist film.

More specifically, the adjustment colorant transmits excitation light EL emitted from an LED 4, and selectively transmits light in wavelength bands corresponding to the three primary colors, from among fluorescence FL emitted from the excited fluorescent colorant, while absorbing the remaining light of unnecessary wavelengths. For the adjustment colorant, pigments or dyes for color filters may be used. That is, the red fluorescent layer 2R contains a red fluorescent colorant, and a red adjustment colorant that selectively transmits excitation light EL and light in a red wavelength band; the green fluorescent layer 2G contains a green fluorescent colorant, and a green adjustment colorant that selectively transmits excitation light EL and light in a green wavelength band; the blue fluorescent layer 2B contains a blue fluorescent colorant, and a blue adjustment colorant that selectively transmits excitation light EL and light in a blue wavelength band.

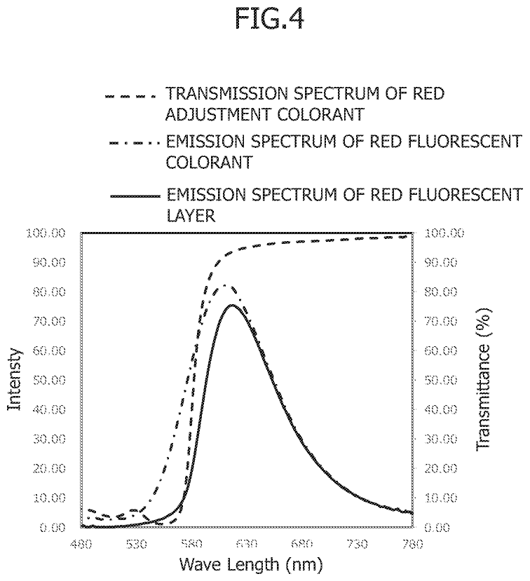

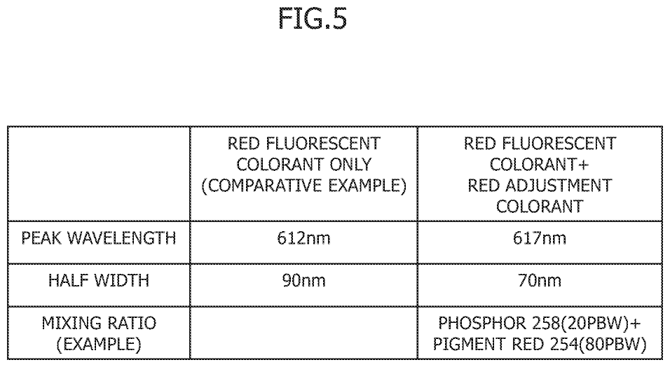

FIG. 4 illustrates emission spectra of the red fluorescent layer 2R containing the red fluorescent colorant and the red adjustment colorant for red color. A broken line indicates a transmission spectrum of the red adjustment colorant, a chain line indicates an emission spectrum of the red fluorescent colorant, and a solid line indicates an emission spectrum of the red fluorescent layer 2R containing the red adjustment colorant and the red fluorescent colorant. FIG. 5 is a table showing the color purity of the red fluorescent layer 2R, comparing with that of a red fluorescent colorant. Here, the red fluorescent colorant used is Phosphor 258, and the red adjustment colorant used is Pigment Red 254. The mixing ratio is such that phosphor 258 is 20 parts by weight and Pigment Red 254 is 80 parts by weight. These colorants and mixing ratio are merely an example, and the present invention is not limited thereto.

As shown in FIG. 5, the red fluorescent layer 2R containing the red fluorescent colorant and the red adjustment colorant, has the emission characteristics that the emission peak is 617 nm and the half width is 70 nm. On the other hand, a red fluorescent colorant has the emission characteristics that the emission peak is 612 nm and the half width is 90 nm. Thus, the red fluorescent layer 2R containing the red fluorescent colorant and the red adjustment colorant, has an emission peak shifted toward a longer wavelength, and has less half width, compared to the red fluorescent colorant. Thus, it should be understood that the red fluorescent layer 2R has the improved color purity.

As shown in FIG. 2, a light shielding member 3 is deposited on a peripheral face 2b of the fluorescent layer 2, which is other than a light emitting surface 2a provided on a display surface side of the fluorescent layer 2. The light shielding member 3 reflects or absorbs excitation light EL and fluorescence FL, and may be made of a metal film, such as aluminum or nickel, which reflects excitation light EL and fluorescence FL, by sputtering or plating, for example. Alternatively, for example, the light shielding member 3 may be formed by applying a black resin that absorbs excitation light EL and fluorescence FL, so as to fill a gap between adjacent fluorescent layers 2. The light shielding member 3 deposited on the light emitting surface 2a of the fluorescent layer 2 can be removed later by various methods, such as photolithography, laser irradiation, or polishing.

In a case in which a metal film is used to form the light shielding member 3, excitation light EL that travels obliquely in a fluorescent layer 2 toward an adjacent fluorescent layer 2 is reflected on the metal film and travels to the inside of the fluorescent layer 2, so that the reflected excitation light EL can be used for excitation of the fluorescent colorant. Thus, it is possible to improve the luminous efficiency of the fluorescent layers 2. Furthermore, since fluorescence FL traveling obliquely in a fluorescent layer 2 is reflected on the metal film, and is then emitted from the light emitting surface 2a of the fluorescent layer 2, it is also possible to improve the light utilization ratio.

Next, a manufacturing method for the full-color LED display panel according to the first embodiment, having the above structure, will be described.

The manufacturing method for the full-color LED display panel according to the first embodiment of the present invention can be roughly divided into a process for manufacturing an LED array substrate, a process for forming a fluorescent layer, and a process for forming a light shielding member. Hereinbelow, each process will be described in order.

### Process for Manufacturing LED Array Substrate

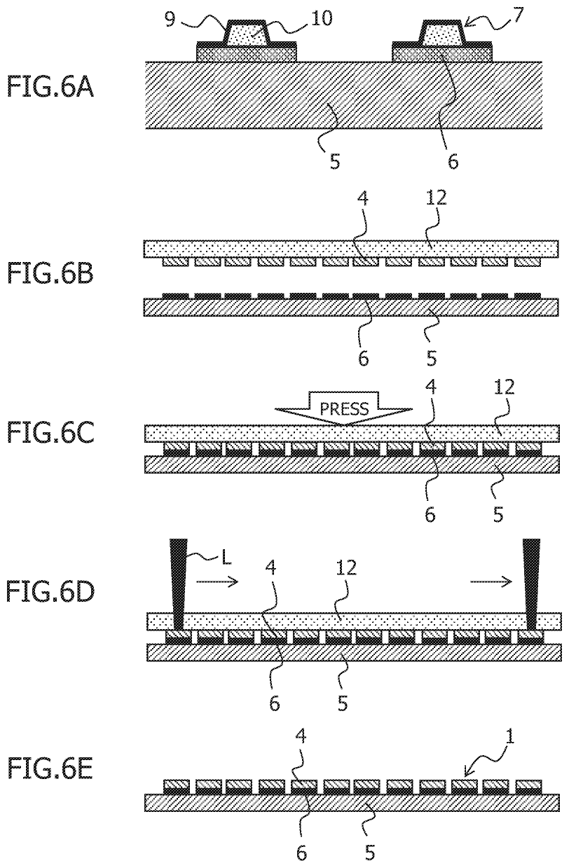

FIGS. 6A to 6E are explanatory views showing the process for manufacturing an LED array substrate.

First, as shown in FIG. 6A, a conductive elastic protrusion 7 is formed on each corresponding electrode pad 6 on the wiring board 5. Specifically, a resist for forming a photo spacer is applied to the entire surface of the wiring board 5, and the resist is then exposed using a photomask 14 and is developed to form a protrusion 10 on each electrode pad 6 by patterning. Then, on each protrusion 10 and the corresponding electrode pad 6, a conductive film 9 of superior conductivity, such as of gold or aluminum, is formed, by sputtering or vapor deposition, for example, to form an elastic protrusion 7.

More specifically, before forming the conductive film 9, a resist layer is formed by photolithography on the periphery of each electrode pad 6 (i.e., except on the electrode pad 6), and after forming the conductive film 9, the resist layer is dissolved with a solution, and thus, the conductive film 9 on the resist layer is lifted off.

The elastic protrusions 7 may be protrusions 10, each made of a conductive photoresist obtained by adding conductive fine particles, such as silver, to a photoresist, or a conductive photoresist containing a conductive polymer. In this case, the elastic protrusions 7 are formed by patterning as the protrusions 10 on the electrode pads 6, by applying a conductive photoresist to the entire upper surface of the wiring board 5 to a predetermined thickness, exposing the photoresist using a photomask, and developing the photoresist.

Since the elastic protrusions 7 are thereby formed by applying a photolithography process, it is possible to secure high precision in position and shape, and it is also possible to easily form the elastic protrusions 7 even when the distance between the electrodes 8 of the LEDs 4 is less than about 10 μm. Therefore, it is possible to manufacture a high-definition, full-color LED display panel.

Furthermore, since the elastic protrusion 7 is configured to contact a corresponding electrode 8 of the LED 4 while being elastically deformed by pressing of the LED 4, it is possible to reliably bring each electrode 8 of multiple LEDs 4 into contact with the elastic protrusions 7 even when the multiple LEDs 4 are simultaneously pressed as described below. Therefore, it is possible to improve the production yield of the full-color LED display panel.

Next, as shown in FIG. 6B, for example, multiple LEDs 4 that are arranged in a matrix form on, for example, a sapphire substrate 12, at the same pitch as a pixel pitch of the LED display panel, and that emit light in the ultraviolet or blue wavelength band, are aligned with the wiring board 5 such that each electrode 8 of each LED 4 is arranged above a corresponding electrode pad 6 on the wiring board 5.

Next, as shown in FIG. 6C, the sapphire substrate 12 is pressed against the wiring board 5, and each electrode 8 of each LED 4 is electrically connected to a corresponding electrode pad 6 of the wiring substrate 5. Then, the LEDs 4 are bonded to the wiring board 5 with an adhesive (not shown). In this case, before bonding the LEDs 4 to the wiring board 5, the wiring board 5 may be supplied with a current, to inspect the turned-on state of each LED 4. Then, only non-defective LEDs 4 may be bonded, excluding an LED 4 determined to be defective in light emission, or a row of LEDs 4 that includes an LED 4 determined to be defective.

Subsequently, as shown in FIG. 6D, each non-defective LED 4 is irradiated with laser light L through the sapphire substrate 12, to perform laser liftoff, so as to separate the irradiated non-defective LED 4 from the sapphire substrate 12. Thereby, as shown in FIG. 6E, an LED array substrate 1 in which multiple LEDs 4 are arranged in a matrix form on the wiring substrate 5 is completed. A spare non-defective LED 4 or a row of spare non-defective LEDs, is supplied to the wiring board 5 at the missing portion corresponding to the defective LED 4 or corresponding to the row of LEDs 4 including the defective LED 4.

### Process for Forming Fluorescent Layer

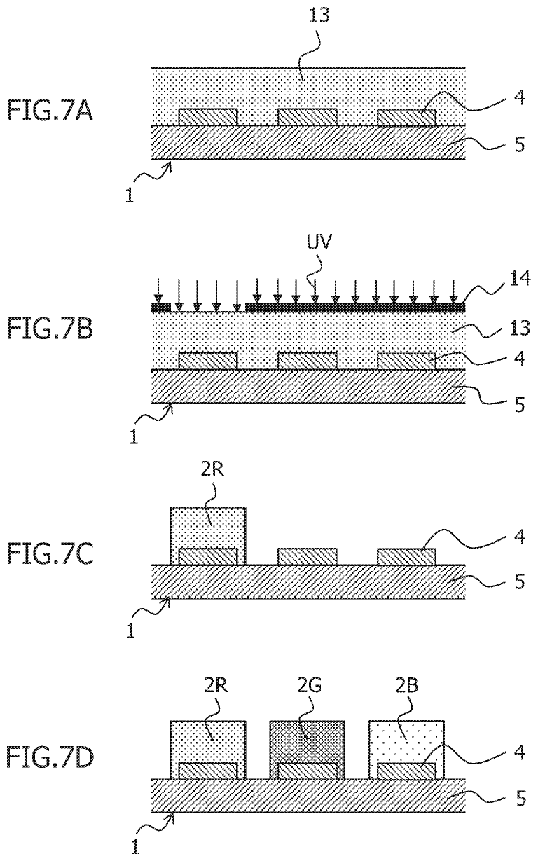

FIGS. 7A to 7D are explanatory views showing the process for forming fluorescent layers.

First, as shown in FIG. 7A, a red fluorescent resist 13, for example, is applied to the LED array substrate 1 by spin coating or spray coating.

Next, as shown in FIG. 7B, the red fluorescent resist 13 on LEDs 4 for red color, is exposed using the photomask 14.

Next, by developing the red fluorescent resist 13 with a predetermined developer, the red fluorescent resist 13 having an island pattern remains on the LEDs 4 for red color, as shown in FIG. 7C, to form the red fluorescent layer 2R.

Then, in a similar manner, a green fluorescent resist and a blue fluorescent resist are subjected to an application process on the LED array substrate 1 and a photolithography process using a photomask, to form a green fluorescent layer 2G on LEDs 4 for green color and a blue fluorescent layer 2B on LEDs 4 for blue color, as shown in FIG. 7D.

### Process for Forming Light Shielding Member

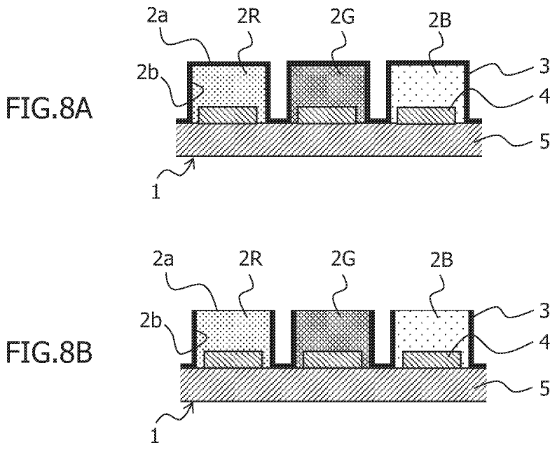

FIGS. 8A and 8B are explanatory views showing the process for forming a light shielding member.

First, as shown in FIG. 8A, as the light shielding member 3, a metal film, such as aluminum or nickel, is formed on the peripheral faces 2b of each fluorescent layer 2 through the light emitting surface 2a of the fluorescent layer 2 to a predetermined thickness by sputtering, for example. In this case, the light shielding member 3 may be formed by forming a metal film by electroless plating, or alternatively, may be formed by applying a photosensitive black resin to the fluorescent layers 2, and then, by curing the applied resin by UV curing, to fill a gap between adjacent fluorescent layers 2 with the black resin.

Then, as shown in FIG. 8B, the cured light shielding member 3 on each light emitting surface 2a of each fluorescent layer 2 is removed by, for example, etching by photolithography, laser irradiation, or polishing. When removing the metal film by laser irradiation, a laser having a wavelength of about 260 nm to about 360 nm may be preferably used. When removing the black resin by laser irradiation, the black resin may be subjected to laser ablation using a laser having a wavelength of about 355 nm or more.

Then, a transparent protective layer (not shown), which transmits visible light, and an antireflection film for preventing external light from being reflected, are formed on the display surface. Thereby, the full-color LED display panel according to the first embodiment of the present invention is completed. When LEDs 4 emitting blue light are used, the blue fluorescent layer 2B may be omitted.

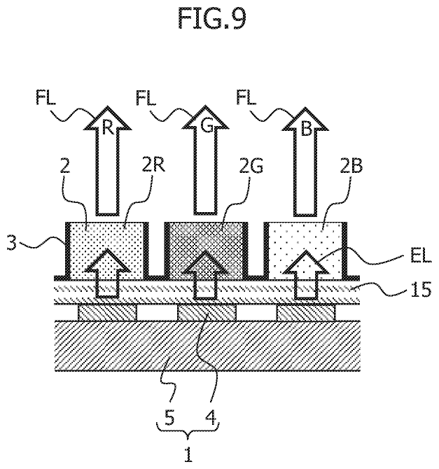

FIG. 9 is an enlarged cross-sectional view of the main part of a full-color LED display panel according to a second embodiment of the present invention.

The second embodiment is different from the first embodiment in that the fluorescent layers 2 and the light shielding member 3 are formed on another transparent substrate 15, which is different from the LED array substrate 1. Hereinbelow, a manufacturing method according to the second embodiment will be described.

The manufacturing method according to the second embodiment can be roughly divided into a process for manufacturing an LED array substrate, a process for manufacturing a fluorescent layer array substrate, and an assembling process.

The process for manufacturing an LED array substrate is the same as that in the manufacturing method according to the first embodiment, and description thereof will be omitted.

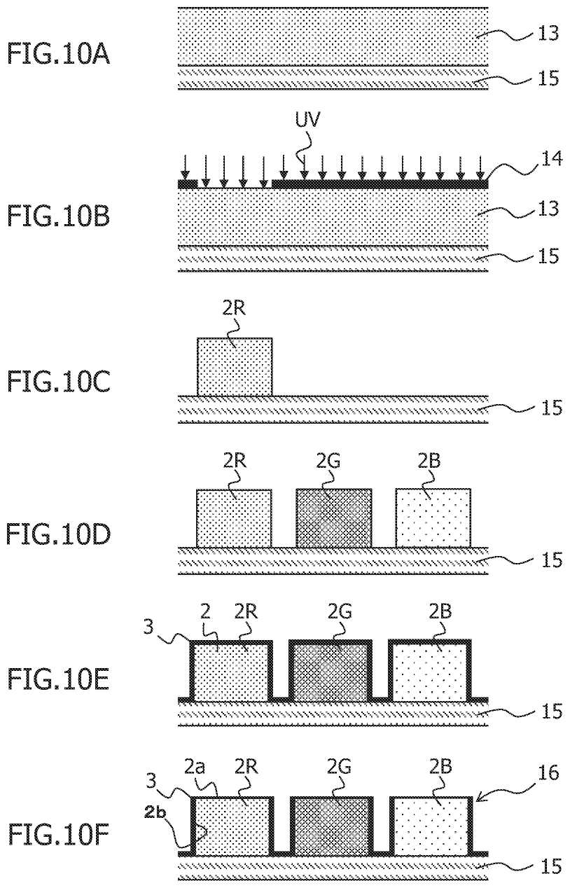

FIGS. 10A to 10F are explanatory views showing the process for manufacturing a fluorescent layer array substrate.

First, as shown in FIG. 10A, a red fluorescent resist 13, for example, is applied to a transparent substrate 15 made of, for example, glass or resin, which transmits ultraviolet light and visible light, by spin coating or spray coating.

Next, as shown in FIG. 10B, the red fluorescent resist 13 is exposed using a photomask 14.

Then, by developing the red fluorescent resist 13 with a predetermined developer, the remaining red fluorescent resist 13 that is developed forms an island pattern, as shown in FIG. 10C. Red fluorescent layer 2R is thereby formed in the island pattern at the same pitch as the arrangement pitch of the LEDs 4 for red color.

Then, in a similar manner, a green fluorescent resist 13 is subjected to an application process on the transparent substrate 15 and a photolithography process using a photomask, and a blue fluorescent resist 13 is subjected to an application process on the transparent substrate 15 and a photolithography process using a photomask. This forms green fluorescent layer 2G in the island pattern at the same pitch as the arrangement pitch of LEDs 4 for green color, and blue fluorescent layer 2B in the island pattern at the same pitch as the arrangement pitch of LEDs 4 for blue color, as shown in FIG. 10D.

Next, as shown in FIG. 10E, as the light shielding member 3, a metal film, such as aluminum or nickel, is formed on side faces of each fluorescent layer 2 through the light emitting surface 2a of the fluorescent layer 2 to a predetermined thickness by sputtering, for example. In this case, the light shielding member 3 may be formed by forming a metal film by electroless plating, or alternatively, may be formed by applying a photosensitive black resin to the fluorescent layers 2, and then, by curing the applied resin by UV curing, to fill a gap between adjacent fluorescent layers 2 with the black resin.

Then, as shown in FIG. 10F, the light shielding member 3 on the light emitting surface 2a of each fluorescent layer 2 is removed by, for example, etching by photolithography, laser irradiation, or polishing. In this way, a fluorescent layer array substrate 16 is thus manufactured in which each fluorescent layer 2 has the peripheral faces 2b, which are other than the light emitting surface 2a, and each of which is provided with the light shielding member 3.

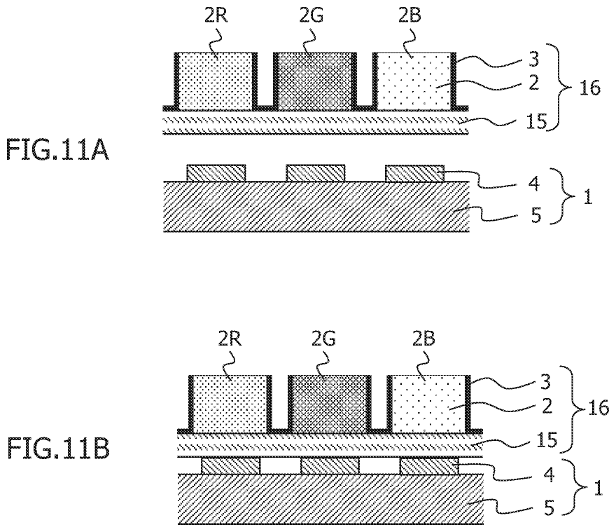

FIGS. 11A and 11B are explanatory views showing the assembling process. First, as shown in FIG. 11A, the fluorescent layer array substrate 16 is arranged above the LED array substrate 1. The fluorescent layer array substrate 16 and the LED array substrate 1 are aligned by using alignment marks (not shown) formed in advance on the fluorescent layer array substrate 16 and alignment marks (not shown) formed in advance on the LED array substrate 1, such that each fluorescent layer 2 on the fluorescent layer array substrate 16 is positioned above corresponding LEDs 4 on the LED array substrate 1.

Next, as shown in FIG. 11B, the fluorescent layer array substrate 16 and the LED array substrate 1 are held together under pressure while maintaining the alignment state, and are bonded with an adhesive (not shown). Thereby, the full-color LED display panel according to the second embodiment of the present invention is completed. As in the first embodiment, when LEDs 4 emitting blue light are used, the blue fluorescent layer 2B may be omitted.

In the second embodiment, formation of a protective layer and an antireflection film on the fluorescent layer 2 may be performed after the formation of the fluorescent layer array substrate 16, or alternatively, after the completion of the assembling process.

Although in the above description the LEDs 4 are light emitting diodes manufactured using gallium nitride (GaN) as a main material, the present invention is not limited thereto, and the LEDs 4 may include organic EL (organic electroluminescent) diodes. Therefore, the LEDs 4 of the LED array substrate 1 may be formed of an organic EL layer that emits light in the ultraviolet or blue wavelength band.

It should be noted that the entire contents of Japanese Patent Application No. 2018-018009, filed on Feb. 5, 2018, from which convention priority is claimed, is incorporated herein by reference.

It should also be understood that many modifications and variations of the described embodiments of the invention will be apparent to one of ordinary skill in the art, without departing from the spirit and scope of the present invention as claimed in the appended claims.

What is claimed is:

1. A full-color LED display panel comprising:
an LED array substrate in which multiple LEDs are arranged in a matrix form on a wiring board, each LED emitting light in an ultraviolet or blue wavelength band;
multiple fluorescent layers configured to perform wavelength conversion by being excited by excitation light emitted from a corresponding LED and by emitting fluorescence of a corresponding color, each fluorescent layer being formed in an island pattern, on at least one corresponding LED for red, green, or blue color, and being made of a fluorescent resist containing a fluorescent colorant uniformly dispersed in a photosensitive resin; and
a light shielding member that reflects or absorbs excitation light and fluorescence, and is deposited on a peripheral face of each fluorescent layer, which is other than a light emitting surface.

2. The full-color LED display panel according to claim 1, wherein the light shielding member is a metal film that reflects excitation light.

3. The full-color LED display panel according to claim 1, wherein the fluorescent resist further contains, in addition to the fluorescent colorant, an adjustment colorant that selectively transmits light in a predetermined wavelength band.

4. A method for manufacturing a full-color LED display panel, the method comprising:
a first step of arranging multiple LEDs in a matrix form on a wiring board to form an LED array substrate, each LED emitting light in an ultraviolet or blue wavelength band;
a second step of exposing a fluorescent resist containing a fluorescent colorant uniformly dispersed in a photosensitive resin, and then, developing the fluorescent resist, to form multiple fluorescent layers configured to perform wavelength conversion by being excited by excitation light emitted from an LED and by emitting fluorescence of a corresponding color, each fluorescent layer being formed in an island pattern, on at least one corresponding LED for red, green, or blue color; and
a third step of depositing, on a peripheral face of each fluorescent layer, which is other than a light emitting surface, a light shielding member that reflects or absorbs excitation light and fluorescence.

5. The method for manufacturing a full-color LED display panel, according to claim 4, wherein the light shielding member is a metal film that reflects excitation light.

6. The method for manufacturing a full-color LED display panel, according to claim 4, wherein the third step comprises forming the light shielding member on a side face of the fluorescent layer, and then, removing a formed light shielding member deposited on the light emitting surface.

7. The method for manufacturing a full-color LED display panel, according to claim 4, wherein the fluorescent resist further contains, in addition to the fluorescent colorant, an adjustment colorant that selectively transmits light in a predetermined wavelength band.
